(19) United States
(12) Patent Application Publication
(10) Pub. No.: US 2006/0121681 A1
(43) Pub. Date: Jun. 8, 2006

(54) Method for forming halo/pocket implants through an L-shaped sidewall spacer

(75) Inventor: Mahalingam Nandakumar, Richardson, TX (US)

Correspondence Address: TEXAS INSTRUMENTS INCORPORATED, P O BOX 655474, M/S 3999, DALLAS, TX, 75265, US

(73) Assignee: Texas Instruments, Inc., Dallas, TX (US)

(21) Appl. No.: 11/002,764

(22) Filed: Dec. 2, 2004

(51) Int. Cl. H01L 21/336; H01L 21/425

(52) U.S. Cl. 438/302; 438/525

(57) ABSTRACT

The present invention provides a method for manufacturing a semiconductor device and a method for manufacturing an integrated circuit including the same. The method for manufacturing the semiconductor device, among other steps, includes forming an L-shaped spacer (410) proximate a sidewall of a gate structure (130) located over a substrate (110), and implanting halo/pocket implant regions (620) through the L-shaped spacer (410) and in the substrate (110).

### TECHNICAL FIELD OF THE INVENTION

The present invention is directed, in general, to a method for manufacturing a semiconductor device and, more specifically, to a method for forming halo/pocket implants, and a method for manufacturing an integrated circuit including the aforementioned method for forming halo/pocket implants.

### BACKGROUND OF THE INVENTION

There exists a continuing need to improve semiconductor device performance and further scale semiconductor devices. As the semiconductor devices continue to scale, the distance between transistors on a given wafer, or so called pitch, also continues to scale. Unfortunately, as the pitch of transistors decreases certain problems that were previously not an issue now are.

One such issue is the proper placement of halo/pocket implants within or near the channel regions of the transistor devices. Typically, the halo/pocket implants are implanted at a specific dose, energy and angle to achieve a specific halo/pocket implant at a precise location. Generally, the energy and dose are kept at relatively low values so as to not increase the parasitic capacitance in the channel region of the devices. Thus, to achieve proper placement the angle of the halo/pocket implant is increased (e.g., from vertical) to force the halo/pocket implant further into or near the channel region.

Unfortunately, as the pitch decreases, the maximum attainable angle also decreases. This nevertheless limits the possibilities for placement of the halo/pocket implants, without increasing either the implant dose or energy. As discussed above, increasing either one or both of the implant dose or energy is highly undesirable.

Accordingly, what is needed in the art is a method for forming halo/pocket implants in a substrate of a semiconductor device that can accommodate the constantly decreasing pitch values that the industry will continue to experience.

### SUMMARY OF THE INVENTION

To address the above-discussed deficiencies of the prior art, the present invention provides a method for manufacturing a semiconductor device and a method for manufacturing an integrated circuit including the same. The method for manufacturing the semiconductor device, among other steps, includes forming an L-shaped spacer proximate a sidewall of a gate structure located over a substrate, and implanting halo/pocket regions through the L-shaped spacer and in the substrate.

The method for manufacturing an integrated circuit, on the other hand, without limitation includes: (1) forming semiconductor devices over a substrate, including, forming an L-shaped spacer proximate a sidewall of a gate structure located over a substrate, and implanting halo/pocket regions through the L-shaped spacer and in the substrate, and (2) forming interconnects within interlevel dielectric layers located over the substrate, the interconnects contacting the semiconductor devices and thereby forming an operational integrated circuit.

The foregoing has outlined preferred and alternative features of the present invention so that those skilled in the art may better understand the detailed description of the invention that follows. Additional features of the invention will be described hereinafter that form the subject of the claims of the invention. Those skilled in the art should appreciate that they can readily use the disclosed conception and specific embodiment as a basis for designing or modifying other structures for carrying out the same purposes of the present invention. Those skilled in the art should also realize that such equivalent constructions do not depart from the spirit and scope of the invention.

### BRIEF DESCRIPTION OF THE DRAWINGS

The invention is best understood from the following detailed description when read with the accompanying FIGUREs. It is emphasized that in accordance with the standard practice in the semiconductor industry, various features are not drawn to scale. In fact, the dimensions of the various features may be arbitrarily increased or reduced for clarity of discussion. Reference is now made to the following descriptions taken in conjunction with the accompanying drawings, in which:

FIG. 1 illustrates a cross-sectional view of a partially completed semiconductor device manufactured in accordance with the principles of the present invention;

FIG. 2 illustrates a cross-sectional view of the partially completed semiconductor device illustrated in FIG. 1 after forming a first material layer over the substrate;

FIG. 3 illustrates a cross-sectional view of the partially completed semiconductor device illustrated in FIG. 2 after forming a second material layer over the first material layer;

FIG. 4 illustrates a cross-sectional view of the partially completed semiconductor device illustrated in FIG. 3 after subjecting the first material layer and second material layer to an etch;

FIG. 5 illustrates a cross-sectional view of the partially completed semiconductor device illustrated in FIG. 4 after removing the offset spacers and exposing the L-shaped spacer;

FIG. 6 illustrates a cross-sectional view of the partially completed semiconductor device illustrated in FIG. 5 after formation of lightly doped source/drain extension implants and halo/pocket regions within the substrate;

FIG. 7 illustrates a cross-sectional view of the partially completed semiconductor device illustrated in FIG. 6 after forming portions of the gate sidewall spacers;

FIG. 8 illustrates a cross-sectional view of the partially completed semiconductor device illustrated in FIG. 7 after the formation of highly doped source/drain implants within the substrate; and

FIG. 9 illustrates a cross-sectional view of a conventional integrated circuit (IC) incorporating a semiconductor device constructed according to the principles of the present invention.

### DETAILED DESCRIPTION

The present invention is somewhat based on the unique acknowledgment that accurate halo/pocket region placement in a semiconductor device is going to become a significant problem as device size continues to decrease, specifically as the pitch between ones of the devices gets smaller and smaller. Given this acknowledgment, the present invention recognized that by using a specifically tailored sidewall spacer that the halo/pocket implant could penetrate through (e.g., including shape, thickness, material, etc. of the sidewall spacer), the pitch problem could be substantially reduced. Therefore, in one embodiment of the invention, the present invention suggests using an L-shaped sidewall spacer that may both define the location of the lightly doped source/drain extension implants, but also allows the halo/pocket implant to penetrate therethrough and form the halo/pocket regions in or near the channel region of the device.

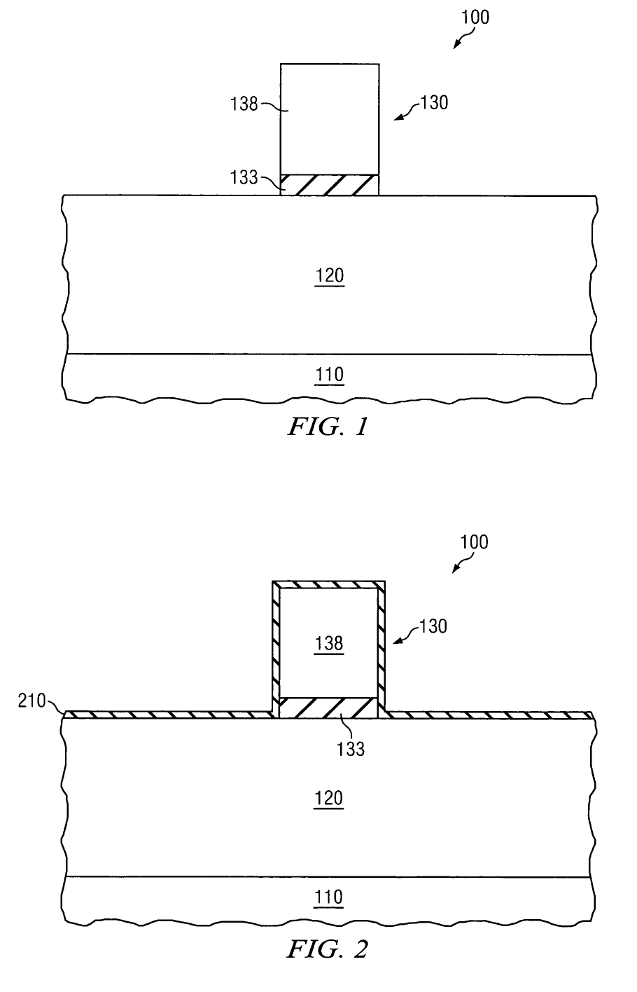

Turning now to FIGS. 1-8, illustrated are cross-sectional views of detailed manufacturing steps illustrating how one might manufacture a semiconductor device in accordance with the principles of the present invention. FIG. 1 illustrates a cross-sectional view of a partially completed semiconductor device 100 manufactured in accordance with the principles of the present invention. From the outset, it should be noted that the embodiment of FIGS. 1-8 will be discussed as an n-channel metal oxide semiconductor (NMOS) device. In an alternative embodiment, all the dopant types, except for possibly the substrate dopant, could be reversed, resulting in a p-channel metal oxide semiconductor (PMOS) device. However, at least with regard to FIGS. 1-8, no further reference to this opposite scheme will be discussed.

In the advantageous embodiment shown, the partially completed semiconductor device 100 of FIG. 1 includes a substrate 110. The substrate 110 may, in an exemplary embodiment, be any layer located in the partially completed semiconductor device 100, including a wafer itself or a layer located above the wafer (e.g., epitaxial layer). In the embodiment illustrated in FIG. 1, the substrate 110 is a P-type substrate; however, one skilled in the art understands that the substrate 110 could more than likely be an N-type substrate without departing from the scope of the present invention.

Located within the substrate 110 in the embodiment shown in FIG. 1 is a well region 120. The well region 120 in the embodiment illustrated in FIG. 1 contains a P-type dopant. For example, the well region 120 would likely be doped with a P-type dopant dose ranging from about 1E13 atoms/cm² to about 1E14 atoms/cm² and at an energy ranging from about 100 keV to about 500 keV. This results in the well region 120 having a peak dopant concentration ranging from about 5E17 atoms/cm³ to about 1E19 atoms/cm³. Those skilled in the art understand that in certain circumstances where the P-type substrate 110 dopant concentration is high enough, the well region 120 may be excluded.

Located over the substrate 110 in the embodiment of FIG. 1 is a gate structure 130. The gate structure 130 includes a gate oxide 133 and a polysilicon gate electrode 138. The gate oxide 133 may comprise a number of different materials and stay within the scope of the present invention. For example, the gate oxide 133 may comprise silicon dioxide, oxynitride or in an alternative embodiment comprise a high dielectric constant (K) material. In the illustrative embodiment of FIG. 1, however, the gate oxide 133 is a silicon dioxide layer having a thickness ranging from about 0.5 nm to about 100 nm. As those skilled in the art appreciate, these thicknesses cover both lower voltage devices as well as power devices. As one would expect, the present invention is equally applicable to both, wherein breakdown voltage improvements result in the power devices.

Any one of a plurality of manufacturing techniques could be used to form the gate oxide 133. For example, the gate oxide 133 may be either grown or deposited. Additionally, the growth or deposition steps may require a significant number of different temperatures, pressures, gasses, flow rates, etc.

While the advantageous embodiment of FIG. 1 discloses that the polysilicon gate electrode 138 comprises standard polysilicon, other embodiments exist where the polysilicon gate electrode 138, or at least a portion thereof, comprises amorphous polysilicon material, a metal material, or fully silicided metal material. The amorphous polysilicon embodiment may be particularly useful when a substantially planar upper surface of the polysilicon gate electrode 138 is desired.

The deposition conditions for the polysilicon gate electrode 138 may vary, however, if the polysilicon gate electrode 138 were to comprise standard polysilicon, such as the instance in FIG. 1, the polysilicon gate electrode 138 could be deposited using a pressure ranging from about 100 torr to about 300 torr, a temperature ranging from about 620° C. to about 700° C., and a SiH₄ or Si₂H₆ gas flow ranging from about 50 sccm to about 150 sccm. If, however, amorphous polysilicon were desired, the amorphous polysilicon gate electrode could be deposited using a pressure ranging from about 100 torr to about 300 torr, a temperature ranging from about 450° C. to about 550° C., and a SiH₄ or Si₂H₆ gas flow ranging from about 100 sccm to about 300 sccm. In any instance, the polysilicon gate electrode 138 desirably has a thickness ranging from about 50 nm to about 150 nm.

Turning briefly to FIG. 2 illustrated is a cross-sectional view of the partially completed semiconductor device 100 illustrated in FIG. 1 after forming a first material layer 210 over the substrate 110. The first material layer 210, in the embodiment shown, comprises any material that is currently known or hereafter discovered for use as a sidewall spacer in a semiconductor device. Two well-known materials that the first material layer 210 may comprise are an oxide, nitride or oxynitride. Nevertheless, the embodiment of the present invention discussed with respect to FIGS. 1-8, has the first material layer 210 comprising an oxide.

The thickness of the first material layer 210 should be specifically designed to allow certain dopants at certain energies and doses to penetrate therethrough (e.g., during an implant step), while retarding other dopants at lesser energies or doses from penetrating therethrough. Initially, it should be noted that the exact range of thicknesses is highly dependent on the material being used, and the energies as well as doses that are desired to pass an implant therethrough and not pass an implant therethrough. However, in one exemplary embodiment of the invention the thickness of the first material layer 210 ranges from about 2 nm to about 20 nm.

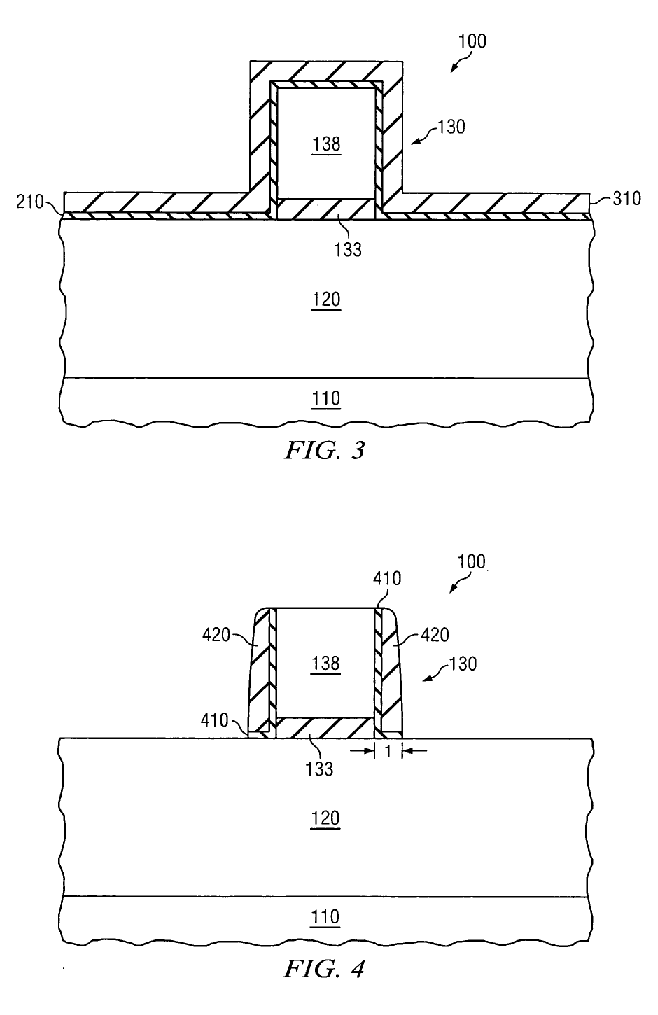

Turning now to FIG. 3 illustrated is a cross-sectional view of the partially completed semiconductor device 100 illustrated in FIG. 2 after forming a second material layer 310 over the first material layer 210. The second material layer 310 is designed to complement the first material layer 210. For instance, the second material layer 310 may also be any known or hereafter discovered material used as a sidewall spacer in a semiconductor device, however, it should typically be a different material from the first material layer 210, thus having a different etch selectivity.

In the current embodiment shown wherein the first material layer 210 is an oxide, an exemplary embodiment has the second material layer 310 comprising a nitride. Again, if the first material layer 210 were to comprise a nitride as previously discussed, the second material layer 310 could easily then comprise an oxide or another similar material. If the first material layer 210 were to comprise an oxynitride then the second material layer 310 could easily comprise a carbide.

The thickness of the second material layer 310, similar to the first material layer 210 but for different reasons, should be specifically tailored for the semiconductor device 100. As will be illustrated in subsequent FIGUREs, the thickness of the second material layer 310 substantially defines the distance that the lightly doped source/drain extension implants 610 (FIG. 6) will be located from the gate structure 130. A thicker second material layer 310 will cause the lightly doped source/drain extension implants 610 (FIG. 6) to be located further from the gate structure 130 and a thinner second material layer 310 will cause the lightly doped source/drain extension implants 610 (FIG. 6) to be located closer to the gate structure 130. Nevertheless, the thickness of the second material layer 310 may be tuned to optimize the resistance of the LDD region and short channel effects.

Obviously then, the thickness of the second material layer 310 is up to the design of the device. Nevertheless, it has been observed that a second material layer 310 thickness ranging from about 2 nm to about 20 nm works extremely well. Notwithstanding, the present invention should not be limited to any disclosed thickness, as other thicknesses may or may not be suitable.

The second material layer 310 may be formed using a number of different processes. If the second material layer 310 were an oxide as a result of the first material layer 210 comprising a nitride, the second material layer 310 would at least initially need to be deposited. The second material layer 310 could then be finished using an oxidation process. As those skilled in the art are aware, the first deposition process allows the oxide layer to form over the first material layer 210 when it does not comprise silicon.

Turning now to FIG. 4, illustrated is a cross-sectional view of the partially completed semiconductor device 100 illustrated in FIG. 3 after subjecting the first material layer 210 and second material layer 310 to an etch. In the specific embodiment of FIG. 3 the first material layer 210 and the second material layer 310 are subjected to an anisotropic etch resulting in an L-shaped spacer 410 and an offset spacer 420. Those skilled in the art understand the specific etches that could be used to define the L-shaped spacer 410 and the offset spacer 420.

As is illustrated, the thickness of the second material layer 310, after being subjected to the etch, defines the length (1) of the lower portion of the L-shaped spacer 410. As previously mentioned, this then substantially defines the distance that the lightly doped source/drain extension implants 610 (FIG. 6) will be located from the gate structure 130. In an exemplary embodiment, the lower portion of the L-shaped spacer 410 should have a length (1) ranging from about 2 nm to about 20 nm.

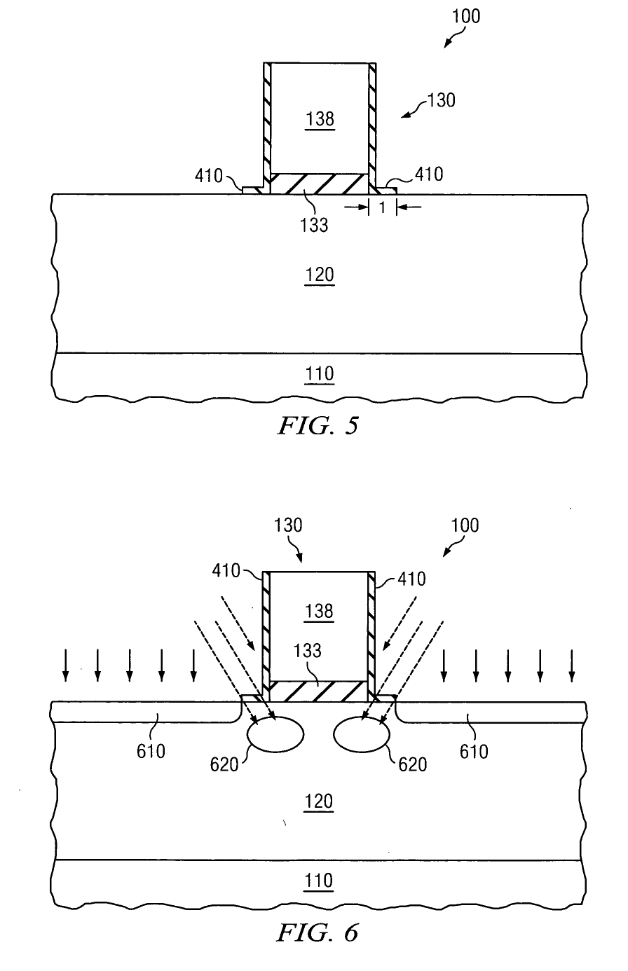

Turning now to FIG. 5, illustrated is a cross-sectional view of the partially completed semiconductor device 100 illustrated in FIG. 4 after removing the offset spacers 420 and exposing the L-shaped spacers 410. A variety of different etches that are highly selective to the offset spacers 420 could be used to remove the offset spacers 420 and leave the L-shaped spacers 410. One example of a suitable etch would be hot phosphoric acid. Other etches could nonetheless be used.

Turning now to FIG. 6, illustrated is a cross-sectional view of the partially completed semiconductor device 100 illustrated in FIG. 5 after formation of lightly doped source/drain extension implants 610 and halo/pocket regions 620 within the substrate 110. The lightly doped source/drain extension implants 610 are conventionally formed and generally have a peak dopant concentration ranging from about 1E19 atoms/cm³ to about 2E20 atoms/cm³. As is standard in the industry, the lightly doped source/drain extension implants 610 have a dopant type opposite to that of the well region 120 they are located within. Accordingly, the lightly doped source/drain extension implants 610 are doped with an N-type dopant in the illustrative embodiment shown in FIG. 6.

The dose and energy used to form the lightly doped source/drain extension implants 610 may vary greatly. In one embodiment of the invention, however, the energy used to implant the lightly doped source/drain extension implants 610 ranges from about 1 keV to about 6 keV, and more preferably from about 1 keV to about 3 keV. Similarly, in one embodiment of the invention the dose used to implant the lightly doped source/drain extension implants 610 ranges from about 1E14 atoms/cm² to about 2E15 atoms/cm², and more preferably from about 2E14 atoms/cm² to about 1E15 atoms/cm². It is important that is during the implanting of the lightly doped source/drain extension implants 610, that the energy and dose are low enough not to substantially implant through the L-shaped spacer 410. When the energy and dose are low enough, the length (1) of the L-shaped spacer 410 substantially defines the position of the lightly doped source/drain extension implants 610 from the gate structure 130.

The halo/pocket regions 620, on the other hand, generally have a peak dopant concentration ranging from about 1E17 atoms/cm³ to about 5E19 atoms/cm³. As is standard in the industry, the halo/pocket regions 620 have a dopant type opposite to that of the lightly doped source/drain extension implants 610. Accordingly, the halo/pocket regions 620 are doped with a P-type dopant in the illustrative embodiment shown in FIG. 6.

The dose, energy and angle used to form the halo/pocket regions 620 may also vary greatly. In one embodiment of the invention, however, the energy used to implant the halo/pocket regions 620 ranges from about 5 keV to about 20 keV, and more preferably from about 5 keV to about 12 keV. Similarly, in one embodiment of the invention the dose used to implant the halo/pocket regions 620 ranges from about 4E12 atoms/cm² to about 2E14 atoms/cm², and more preferably from about 1E13 atoms/cm² to about 1E14 atoms/cm². It is important that is during the implanting of the halo/pocket regions 620, that the energy and/or dose are high enough to implant through the L-shaped spacers 410. When the energy and/or dose are high enough, the halo/pocket regions 620 can implant through the L-shaped spacers 410 and more easily be positioned in a desired location in or near a channel region of the semiconductor device 100. Therefore, in direct contrast to the lightly doped source/drain extension implant 610, the L-shaped spacer 410 does not substantially define the position of the halo/pocket regions 620 from the gate structure 130.

Because the L-shaped spacer 410 allows the halo/pocket regions 620 to implant therethrough, which is in direct contrast to prior art structures, the implant angle used to form the halo/pocket regions 620 may be substantially decreased, as discussed above. For example, using the energy and dose ranges disclosed above, the implant angle could range from about 0 degrees to about 45 degrees, and more preferably from about 10 degrees to about 30 degrees. Moreover, this allows the use of lower angle halo/pocket implants to accommodate next generation devices having substantially decreased pitch values.

The discussion with respect to FIG. 6 indicates that the lightly doped source/drain extension implants 610 are formed prior to the halo/pocket regions 620. This is not always the case as the order of forming the different implants 610, 620 may be easily swapped. Additionally, the lightly doped source/drain extension implants 610 are illustrated as vertical implants, however, angled implants could also be used for the lightly doped source/drain extension implants 610. Many other variations, not described, could also be made to the process discussed with respect to FIG. 6. Additionally, pre or post amorphization implants, such as Sb, Ge, F, may be conducted along with the source/drain extension implants 610.

Turning now to FIG. 7, illustrated is a cross-sectional view of the partially completed semiconductor device 100 illustrated in FIG. 6 after forming portions of gate sidewall spacers 710. Particularly, a cap oxide 713, L-shaped nitride spacers 715 and sidewall oxides 718 complete the gate sidewall spacers 710. The cap oxide 713, among other purposes, has the job of preventing the L-shaped nitride spacers 715 from directly contacting the substrate 110. Most likely, the cap oxide 713 will be deposited over the partially completed semiconductor device 100 using a process similar to that used to form the first material layer 210. In an alternative embodiment, not shown, the cap oxide 713 is removed from a region above the lightly doped source/drain extension implants 610.

The L-shaped nitride spacers 715 may comprise any type of nitride, however, in an exemplary embodiment the L-shaped nitride spacers 715 comprise a nitride material that includes carbon. The carbon content, which may range from about 5% to about 10% of the L-shaped nitride spacers 715, is included within the L-shaped nitride spacers 715 to change the rate at which they etch. In the embodiment where the L-shaped nitride spacers 715 include carbon, the L-shaped nitride spacers 715 may be deposited using bis t-butylaminosilane (BTBAS) and ammonia (NH₃) precursors in a CVD reactor. Advantageously, the carbon causes the L-shaped nitride spacers 715 to etch at a slower rate than a traditional nitride layer. In an exemplary situation, after having been annealed using a temperature ranging from about 1000° C. to about 1100° C., the carbon causes the L-shaped nitride spacers 715 to have an etch selectivity of about 50:1 when compared to the traditional nitride layer.

The sidewall oxides 718 that are located over the L-shaped nitride spacers 715 are conventional. In the given embodiment of FIG. 7, the sidewall oxides 718 were blanket deposited and then subjected to an anisotropic etch. The resulting sidewall oxides 718 complete the gate sidewall spacers 710 illustrated in the embodiment of FIG. 7.

A substantial amount of detail has been given regarding the specifics of the gate sidewall spacers 710. Such should not be construed to be limiting on the present invention. For example, certain embodiments exist where only the L-shaped spacer 410 and sidewall oxides 718, or another similar structure, comprise the gate sidewall spacers 710. Other embodiments exist where all the layers shown in FIG. 7 exist, however, the materials and thicknesses are different. Therefore, as previously noted, the detail given with respect to FIGS. 4 thru 7 regarding the gate sidewall spacers should not be used to limit the scope of the present invention.

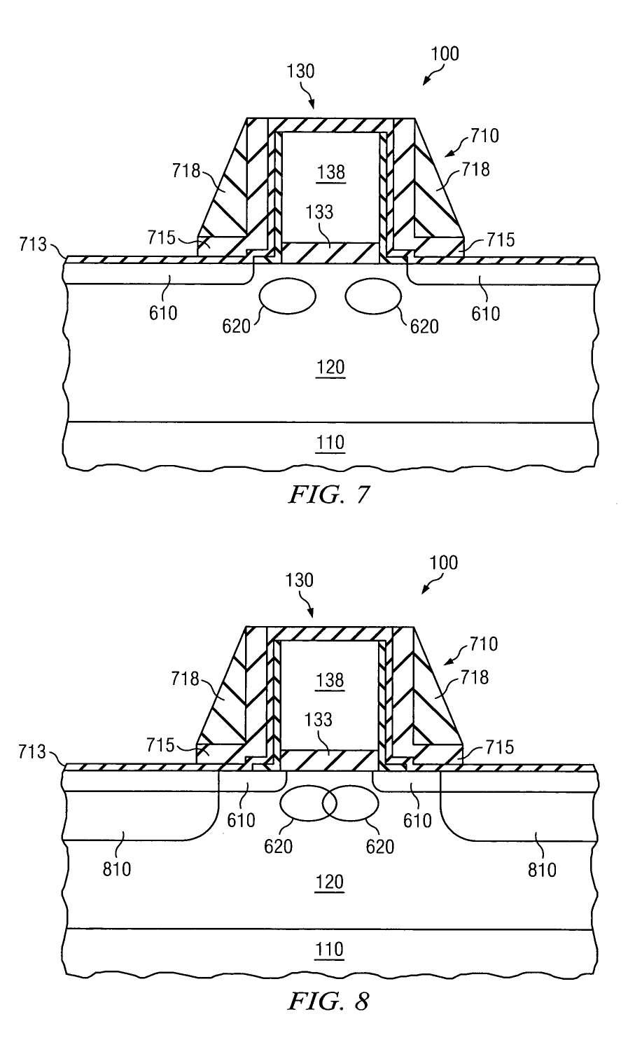

Turning now to FIG. 8, illustrated is a cross-sectional view of the partially completed semiconductor device 100 illustrated in FIG. 7 after the formation of highly doped source/drain implants 810 within the substrate 110. Those skilled in the art understand the conventional processes that could be used to form the highly doped source/drain implants 810. Generally the highly doped source/drain implants 810 have a peak dopant concentration ranging from about 1E18 atoms/cm³ to about 1E21 atoms/cm³. Also, the highly doped source/drain implants 810 should typically have a dopant type opposite to that of the well region 120 they are located within. Accordingly, in the illustrative embodiment shown in FIG. 8, the highly doped source/drain implants 810 are doped with an N-type dopant. After completing the highly doped source/drain implants 810, the manufacture of the partially completed semiconductor device 100 would continue in a conventional fashion, ultimately resulting in a completed semiconductor device.

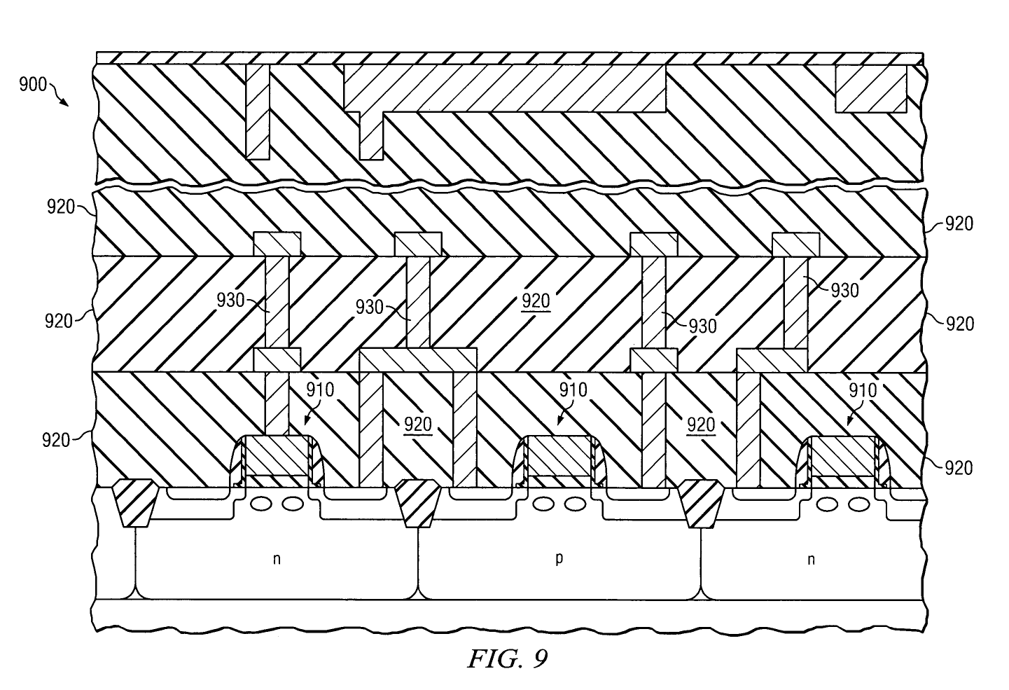

Referring finally to FIG. 9, illustrated is a cross-sectional view of a conventional integrated circuit (IC) 900 incorporating a semiconductor device 910 constructed according to the principles of the present invention. The IC 900 may include devices, such as transistors used to form CMOS devices, BiCMOS devices, Bipolar devices, or other types of devices. The IC 900 may further include passive devices, such as inductors or resistors, or it may also include optical devices or optoelectronic devices. Those skilled in the art are familiar with these various types of devices and their manufacture. In the particular embodiment illustrated in FIG. 9, the IC 900 include semiconductor devices 910 having dielectric layers 920 located thereover. Additionally, interconnect structures 930 are located within the dielectric layers 920 to interconnect various devices, thus, forming the operational integrated circuit 900.

Although the present invention has been described in detail, those skilled in the art should understand that they can make various changes, substitutions and alterations herein without departing from the spirit and scope of the invention in its broadest form.

What is claimed is:

1. A method for manufacturing a semiconductor device, comprising:
forming L-shaped spacers proximate sidewalls of a gate structure located over a substrate; and
implanting halo/pocket regions through the L-shaped spacer and in the substrate.

2. The method as recited in claim 1 wherein implanting halo/pocket regions includes implanting halo/pocket regions at an angle ranging from about 10 degrees to about 30 degrees from vertical.

3. The method as recited in claim 2 wherein implanting halo/pocket regions includes implanting halo/pocket regions using an energy ranging from about 5 KeV to about 20 KeV.

4. The method as recited in claim 1 wherein implanting halo/pocket regions includes implanting halo/pocket regions using an energy ranging from about 5 KeV to about 20 KeV.

5. The method as recited in claim 1 wherein implanting halo/pocket regions includes implanting halo/pocket regions using a dose ranging from about 4E12 atoms/cm² to about 2E14 atoms/cm².

6. The method as recited in claim 1 wherein forming L-shaped spacers includes forming L-shaped spacers having a thickness ranging from about 2 nm to about 20 nm.

7. The method as recited in claim 1 wherein forming L-shaped spacers includes forming L-shaped spacers comprising an oxide, nitride, or combination thereof.

8. The method as recited in claim 1 further including forming lightly doped source/drain extension implants in the substrate, the L-shaped spacers substantially blocking the lightly doped source/drain extension implants from implanting through.

9. The method as recited in claim 8 wherein forming lightly doped source/drain extension implants includes forming lightly doped source/drain extension implants using an energy ranging from about 1 keV to about 6 keV.

10. The method as recited in claim 8 wherein forming lightly doped source/drain extension implants includes forming lightly doped source/drain extension implants using a dose ranging from about 1E14 atoms/cm² to about 2E15 atoms/cm².

11. The method as recited in claim 1 wherein forming L-shaped spacers proximate sidewalls of a gate structure includes forming a layer of a first material over the substrate and a layer of a second material over the first material, subjecting the first and second materials to an anisotropic etch, and removing remaining portions of the second material, thereby resulting in L-shaped spacers.

12. The method as recited in claim 11 wherein the first material is an oxide or oxynitride and the second material is a nitride or carbide, or the first material is a nitride or carbide and the second material is an oxide or oxynitride.

13. A method for manufacturing an integrated circuit, comprising:
forming semiconductor devices over a substrate, including;
forming L-shaped spacers proximate sidewalls of a gate structure located over a substrate; and
implanting halo/pocket regions through the L-shaped spacers and in the substrate; and
forming interconnects within interlevel dielectric layers located over the substrate, the interconnects contacting the semiconductor devices and thereby forming an operational integrated circuit.

14. The method as recited in claim 13 wherein implanting halo/pocket regions includes implanting halo/pocket regions at an angle ranging from about 10 degrees to about 30 degrees from vertical.

15. The method as recited in claim 14 wherein implanting halo/pocket regions includes implanting halo/pocket regions using an energy ranging from about 5 KeV to about 20 KeV.

16. The method as recited in claim 13 wherein implanting halo/pocket regions includes implanting halo/pocket regions using an energy ranging from about 5 KeV to about 20 KeV.

17. The method as recited in claim 13 wherein implanting halo/pocket regions includes implanting halo/pocket regions using a dose ranging from about 4E12 atoms/cm² to about 2E14 atoms/cm².

18. The method as recited in claim 13 wherein forming L-shaped spacers includes forming L-shaped spacers having a thickness ranging from about 2 nm to about 20 nm.

19. The method as recited in claim 13 wherein forming L-shaped spacers includes forming L-shaped spacers comprising an oxide, a nitride, or a combination thereof.

20. The method as recited in claim 13 further including forming lightly doped source/drain extension implants in the substrate, the L-shaped spacers substantially blocking the lightly doped source/drain extension implants from implanting through.

21. The method as recited in claim 20 wherein forming lightly doped source/drain extension implants includes forming lightly doped source/drain extension implants using an energy ranging from about 1 keV to about 6 keV.

22. The method as recited in claim 20 wherein forming lightly doped source/drain extension implants includes forming lightly doped source/drain extension implants using a dose ranging from about 1E14 atoms/cm² to about 2E15 atoms/cm².

23. The method as recited in claim 13 wherein forming L-shaped spacers proximate sidewalls of a gate structure includes forming a layer of a first material over the substrate and a layer of a second material over the first material, subjecting the first and second materials to an anisotropic etch, and removing remaining portions of the second material, thereby resulting in L-shaped spacers.

24. The method as recited in claim 23 wherein the first material is an oxide or oxynitride and the second material is a nitride or carbide, or the first material is a nitride or carbide and the second material is an oxide or oxynitride.
